(19) United States
(12) Patent Application Publication
(10) Pub. No.: US 2025/0038012 A1
(43) Pub. Date: Jan. 30, 2025

(54) SYSTEMS AND METHODS FOR SUBSTRATE COOLING AND/OR HEATING USING COOLING GAS INTRODUCED FROM ANOTHER CHAMBER

(71) Applicant: ASM IP Holding B.V., Almere (NL)

(72) Inventors: Samer Banna, Phoenix, AZ (US); Mandar Deshpande, Phoenix, AZ (US); Salam Harb, Scottsdale, AZ (US)

(21) Appl. No.: 18/783,113

(22) Filed: Jul. 24, 2024

Related U.S. Application Data
(60) Provisional application No. 63/529,480, filed on Jul. 28, 2023.

(51) Int. Cl. H01L 21/67; C23C 16/02; C23C 16/458; C23C 16/56

(52) U.S. Cl. CPC H01L 21/67017; C23C 16/0209; C23C 16/4583; C23C 16/56; H01L 21/67207

(57) ABSTRACT

Substrate processing systems and methods include sealing a gate valve connecting a first chamber (e.g., a load-lock module) and a second chamber (e.g., an equipment front end module), wherein a first side of the first chamber connects to layer deposition equipment and a second side of the first chamber connects to the second chamber via the gate valve. The second chamber receives (i) incoming substrates to be supplied to the first chamber and (ii) outgoing substrates to be removed from the first chamber. In use, a processed substrate is moved from the layer deposition equipment into the first chamber. This processed substrate is cooled by transferring inert gas from the second chamber into the first chamber and into contact with the processed substrate, thereby transferring heat from the processed substrate to the inert gas. After passing over the processed substrate, the inert gas is exhausted from the first chamber.

### CROSS-REFERENCE TO RELATED APPLICATION(S)

This application claims the benefit of U.S. Provisional Application 63/529,480 filed on Jul. 28, 2023, the entire contents of which are incorporated herein by reference.

### FIELD OF THE DISCLOSURE

The present disclosure relates generally to substrate processing systems and methods having substrate cooling and/or heating capabilities. Some more particular aspects of this technology relate to substrate processing systems and methods including two chambers in which gas is introduced into a first chamber from a second chamber, and that gas is used to cool heated substrates and/or to preheat substrates located in the first chamber.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Existing substrate processing systems 100 include “cluster type” systems of the type generally shown in FIG. 1. Such substrate processing systems 100 include a substrate handling chamber 102 that operatively connects with two to four substrate processing chambers 104 via gate valves 106. Each substrate processing chamber 104 is equipped to receive a substrate on a substrate support 108 that holds the substrate during processing (e.g., during material layer deposition as described above).

The substrate handling chamber 102 includes robotic arm 110 used to move substrates into and out of the various substrate processing chambers 104 through the gate valves 106. In use, a gate valve 106 is opened, an end effector 110A of the robotic arm 110 extends through the open gate valve 106 to insert a substrate into or remove a substrate from an interior chamber of the substrate processing chamber 104 (e.g., placing a substrate on or taking a substrate off the substrate support 108). Once the robotic arm 110 is retracted from the substrate processing chamber 104, the gate valve 106 is closed, thereby sealing the substrate processing chamber 104 from the substrate handling chamber 102. Then, other desired actions can take place in the substrate processing chamber 104 and/or the substrate handling chamber 102.

FIG. 1 further shows that this substrate processing system 100 includes a load-lock module 112. The load-lock module 112 is connected with the substrate handling chamber 102 by gate valve 116. The load-lock module 112 includes substrate holding components 114 for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition and other processing in substrate processing chambers 104) and from the substrate handling chamber 102 into the load-lock module 112 (after processing is completed). The load-lock module 112 and gate valve 116 keep the substrates isolated from the environment of the substrate handling chamber 102 until the conditions (e.g., temperature, pressure, content of atmosphere, etc.) within the substrate handling chamber 102 and the load-lock module 112 are ready for the substrate(s) to be transferred.

The load-lock module 112 further is coupled with an equipment front end module 120 via another gate valve 118. The equipment front end module 120 includes a robotic arm 122. The end effector 122A of that robotic arm 122 moves through the gate valve 118 (when opened) to move substrates from the equipment front end module 120 into the load-lock module 112 (for layer deposition and other processing) and from the load-lock module 112 into the equipment front end module 120 (after processing is completed). The robotic arm 122 of the equipment front end module 120 also picks up new substrates for processing from one of the load ports 124A-124C and returns processed substrates to one of the load ports 124A-124C, e.g., to be transported to another location for further processing.

Substrates (e.g., wafers) exiting the chambers in semiconductor deposition tools typically need to be cooled down before exposure to ambient atmospheric conditions in order to maintain the performance integrity of the deposited films. Such cooling typically is achieved in the load-lock module 112 under vacuum conditions, e.g., using cooling plates and a coolant fluid. More specifically, the wafer coming out of a substrate processing chamber 104 via the substrate handling chamber 102 will be placed on a water-cooled cooling plate in the load-lock module 112 in a vacuum environment and left there until it reaches an acceptable temperature (typically below 100° C.). Then the wafer can be moved into the equipment front end module 120 (and beyond).

Conventional semiconductor production systems and methods of this type generally have been acceptable for their intended purpose, but there is room for improvement. For example, the use of such water-cooled cooling plates in the load-lock module 112 makes the design of the substrate processing system 100 more complex, more expensive, and also limits throughput of the substrate processing system 100. Improvements that reduce manufacturing costs, reduce processing time, and/or improve manufacturing efficiency would be welcome advances in the art.

### SUMMARY OF THE DISCLOSURE

Aspects of this technology relate to substrate processing systems and methods having substrate cooling and/or heating capabilities. Some more particular aspects of this technology relate to substrate processing systems and methods including two chambers in which gas in introduced into a first chamber (e.g., a load-lock module) from a second chamber (e.g., an equipment front end module), and that gas is used to cool heated substrates and/or to preheat substrates located in the first chamber.

Substrate processing systems in accordance with at least some examples of this technology include one or more of: (a) a first chamber including: a first side, a second side opposite the first side, a first internal chamber defined between the first side and the second side, and an exhaust outlet that exhausts gas from the first internal chamber, wherein the first side includes one or more openings that are configured to allow substrates to move to and from layer deposition equipment; (b) a second chamber including: a third side, a fourth side opposite the third side, a second internal chamber defined between the third side and the fourth side, and a gas inlet supplying gas to the second internal chamber, wherein the fourth side includes one or more openings that are configured to allow substrates to enter and exit the substrate processing system; (c) a first passageway connecting the first chamber with the second chamber; (d) a first valve configured to control fluid flow through the first passageway; and/or (c) a control system configured to at least partially open the first valve during a substrate cooling operation to allow gas from the second internal chamber to enter the first internal chamber through the first passageway, flow through the first internal chamber, and out of the first internal chamber via the exhaust outlet.

In addition to one or more of the features described above, or as an alternative, the first chamber of substrate processing systems in accordance with some examples of this technology may include: (i) a substrate support member, and (ii) a gas flow direction control device located proximate to an opening in communication with the first valve to direct at least some gas flow entering through the opening via the first passageway away from the substrate support member.

In addition to one or more of the features described above, or as an alternative, the first valve in substrate processing systems in accordance with some examples of this technology may comprise a first gate valve connecting the second side of the first chamber with the third side of the second chamber and defining at least a portion of the first passageway, wherein at least one of the first chamber or the second chamber includes a substrate transfer arm for moving substrates between the first chamber and the second chamber through the first gate valve, wherein during the substrate cooling operation, the control system partially opens the first gate valve a sufficient amount to permit gas to pass from the second internal chamber to the first internal chamber through the first gate valve but an insufficient amount to permit a substrate from being transferred through the first gate valve by the substrate transfer arm.

In addition to one or more of the features described above, or as an alternative, substrate processing systems in accordance with some examples of this technology may further include a gas source connected to the gas inlet and supplying gas to the second internal chamber.

In addition to one or more of the features described above, or as an alternative, the gas source may include nitrogen gas or may comprise a nitrogen gas source.

In addition to one or more of the features described above, or as an alternative, the first valve in substrate processing systems in accordance with some examples of this technology may comprise a first gate valve connecting the second side of the first chamber with the third side of the second chamber and defining at least a portion of the first passageway, wherein the control system is configured to partially open the first gate valve during the substrate cooling operation, and wherein the control system further is configured to more fully open the first gate valve to permit substrate transfer from the first chamber to the second chamber through the first gate valve when the substrate cooling operation is complete.

In addition to one or more of the features described above, or as an alternative, the first valve in substrate processing systems in accordance with some examples of this technology may comprise a first gate valve connecting the second side of the first chamber with the third side of the second chamber and defining at least a portion of the first passageway, the first gate valve including an opening configured to transfer substrates between the first chamber and the second chamber.

In addition to one or more of the features described above, or as an alternative, the first chamber of substrate processing systems in accordance with some examples of this technology may include: (i) a substrate support member located proximate to the first gate valve, and (ii) a gas flow direction control device positioned to direct at least some gas flow entering the first internal chamber via the first gate valve away from the substrate support member.

In addition to one or more of the features described above, or as an alternative, the substrate support member of substrate processing systems in accordance with some examples of this technology may include a rack configured for holding a plurality of substrates in a spaced apart orientation.

In addition to one or more of the features described above, or as an alternative, the first chamber of substrate processing systems in accordance with some examples of this technology may define: (i) a substrate cooling zone to support substrates moved from the layer deposition equipment into the first chamber, and (ii) a substrate preheat zone to support substrates moved from the second chamber to the first chamber via the first gate valve, wherein the substrate preheat zone is located downstream from the substrate cooling zone in a gas direction through the first internal chamber.

In addition to one or more of the features described above, or as an alternative, substrate processing systems in accordance with some examples of this technology may include a second gate valve connecting the second side of the first chamber with the third side of the second chamber, wherein the second gate valve includes an opening configured to transfer substrates between the first chamber and the second chamber.

In addition to one or more of the features described above, or as an alternative, substrate processing systems in accordance with some examples of this technology may include a second valve connecting the second side of the first chamber with the third side of the second chamber, wherein the second valve includes an opening configured to transfer substrates between the first chamber and the second chamber.

Substrate processing methods in accordance with at least some examples of this technology may include one or more of: (a) sealing a first gate valve connecting a first chamber and a second chamber, wherein a first side of the first chamber is connected to layer deposition equipment and a second side of the first chamber is connected to the second chamber via the first gate valve, wherein the second chamber is configured to receive (i) incoming substrates to be supplied to the first chamber through the first gate valve and (ii) outgoing substrates to be removed from the first chamber through the first gate valve; (b) moving a first processed substrate from the layer deposition equipment to the first chamber; (c) supplying an inert gas atmosphere to the second chamber; (d) cooling the first processed substrate by transferring inert gas from the second chamber into the first chamber such that the inert gas flows into contact with the first processed substrate; and/or (e) exhausting the inert gas from the first chamber.

In addition to one or more of the features described above, or as an alternative, transferring the inert gas in substrate processing methods in accordance with some examples of this technology may include partially opening the first gate valve a first amount, wherein the first amount is sufficient to transfer the inert gas but not sufficient to allow a substrate to be transferred through the first gate valve.

In addition to one or more of the features described above, or as an alternative, after the first processed substrate is cooled, substrate processing methods in accordance with some examples of this technology may further include opening the first gate valve to a second amount and moving the first processed substrate from the first chamber to the second chamber through the first gate valve.

In addition to one or more of the features described above, or as an alternative, substrate processing methods in accordance with some examples of this technology may further include one or more of: moving a first unprocessed substrate to a substrate support member located in the first chamber; and preheating the first unprocessed substrate by moving the inert gas in a direction from the first processed substrate to the first unprocessed substrate.

In addition to one or more of the features described above, or as an alternative, substrate processing methods in accordance with some examples of this technology may further include, after preheating, moving the first unprocessed substrate through an opening defined through the first side of the first chamber to the layer deposition equipment.

In addition to one or more of the features described above, or as an alternative, the inert gas used in substrate processing methods in accordance with some examples of this technology may further include nitrogen gas.

In addition to one or more of the features described above, or as an alternative, substrate processing methods in accordance with some examples of this technology may include, during the cooling, transferring the inert gas through the first gate valve.

In addition to one or more of the features described above, or as an alternative, substrate processing methods in accordance with some examples of this technology may include, during the cooling, transferring the inert gas from the second chamber into the first chamber through a valve other than the first gate valve.

This summary is provided to introduce a selection of concepts relating to this technology in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a basic, prior art cluster type substrate processing system;

FIGS. 2A-2C are schematic views showing various features of substrate processing systems and methods in accordance with some examples and aspects of this technology;

FIG. 2D is a flow chart showing operation of a method according to some aspects of this technology, e.g., using the systems of FIGS. 2A-2C;

FIG. 3A is a schematic view showing various features of substrate processing systems and methods in accordance with other examples and aspects of this technology; and

FIG. 3B is a flow chart showing operation of a method according to some aspects of this technology, e.g., using the system of FIG. 3A.

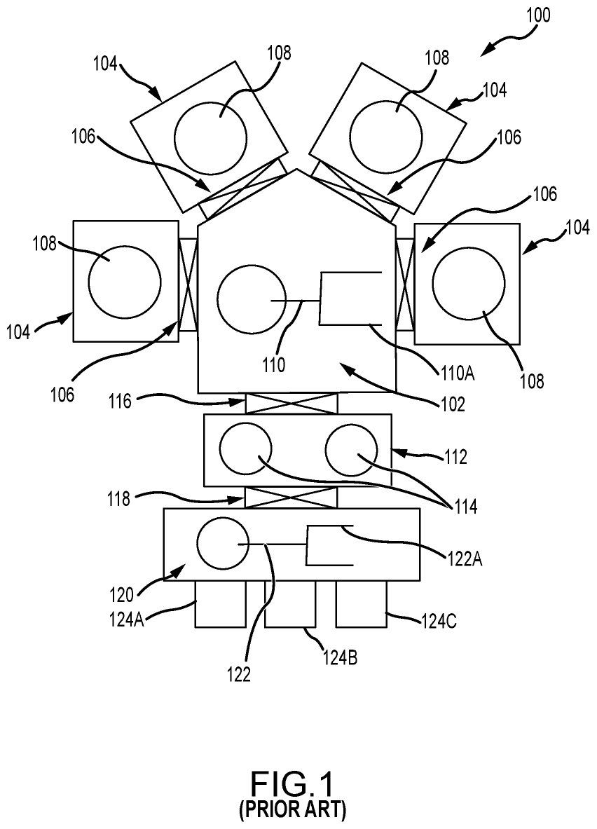

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

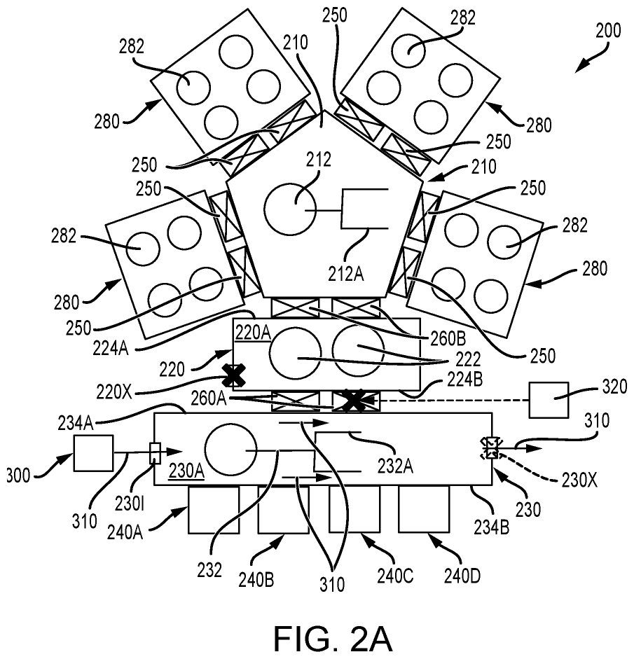

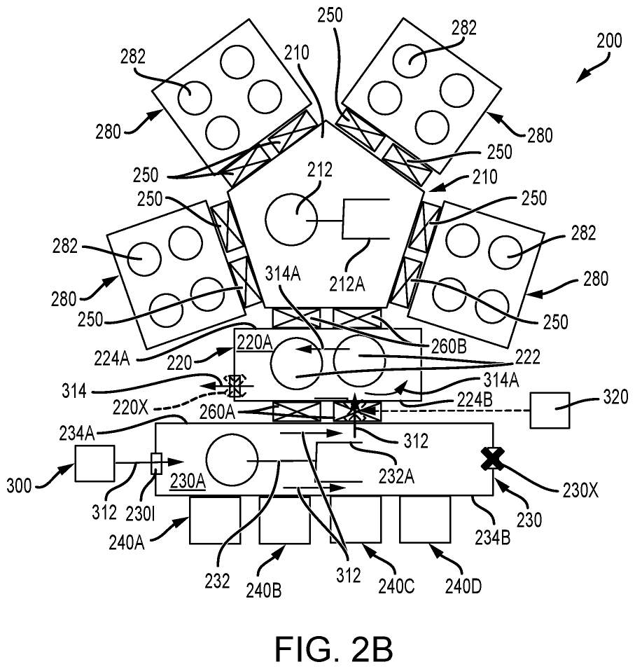

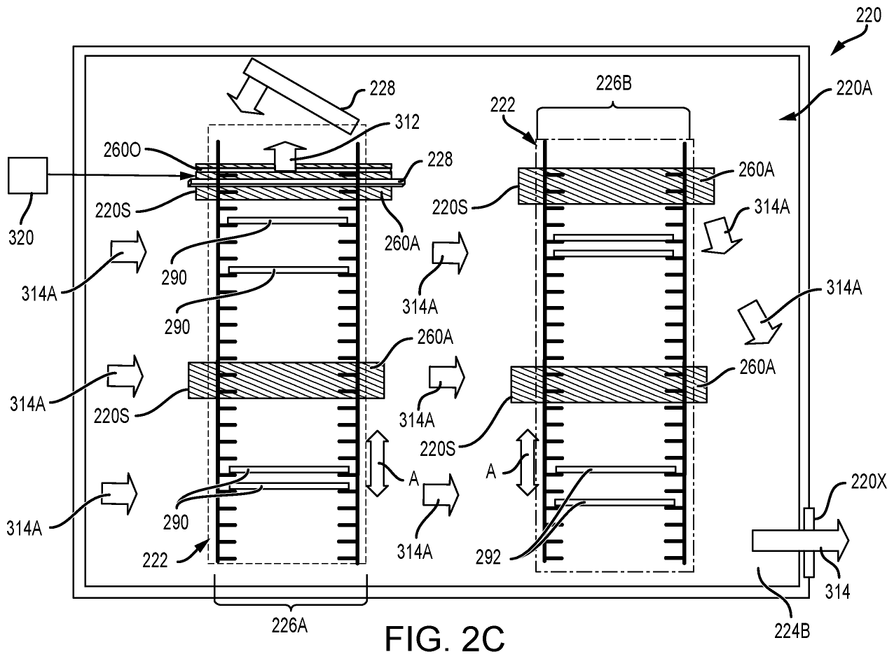

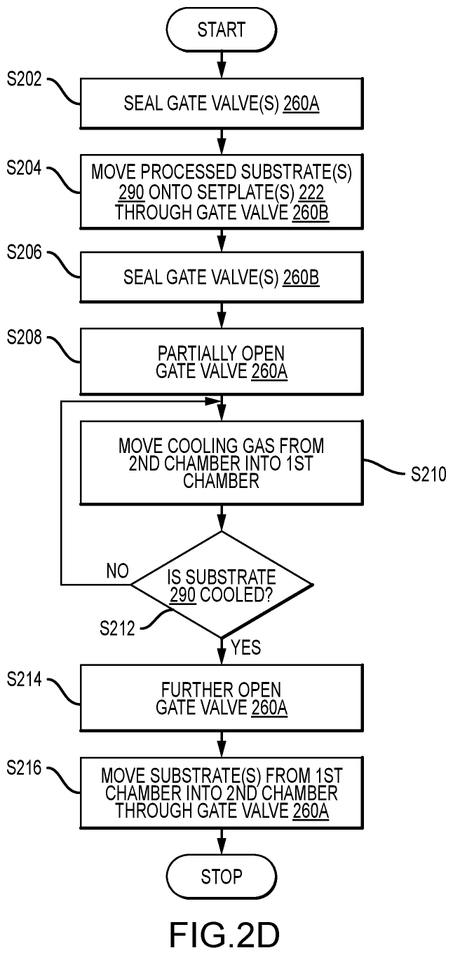

FIG. 2A-2C schematically illustrate an example substrate processing system 200 that includes substrate cooling and/or heating systems and/or uses substrate cooling and/or heating methods in accordance with some examples of this technology. FIGS. 2A and 2B schematically illustrate an overhead view of a substrate processing system 200 (e.g., a “cluster type” semiconductor processing system) having substrate cooling and/or heating system and method features in two different operational states. This specific example substrate processing system 200 includes substrate cooling and/or heating system and method features in association with the load-lock module 220 and the equipment front end module 230. FIG. 2C schematically illustrates additional features regarding some example substrate cooling systems and/or methods as part of an internal chamber 220A of load-lock module 220.

Substrate processing system 200 shown in FIGS. 2A and 2B includes: (a) substrate handling chamber 210 including a robotic arm 212 having an end effector 212A; (b) load-lock module 220 connected at one side or facet of substrate handling chamber 210; and (c) equipment front end module 230 that includes a robotic arm 232 having an end effector 232A connected with an opposite side or facet of the load-lock module 220 from the substrate handling chamber 210. The equipment front end module 230 include or connects with an inert gas source 300 (e.g., a nitrogen gas source) for providing an inert (e.g., nitrogen) gas atmosphere within the equipment front end module 230, as will be described in more detail below. In exemplary embodiments, the inert gas source may be Argon. The equipment front end module 230 receives new substrates (e.g., wafers) for processing into the substrate processing system 200 and discharges processed substrates from the substrate processing system 200 via one or more loading ports 240A-240D. Substrates are moved between the loading port(s) 240A-240D and the load-lock module 220 using robotic arm 232. While four loading ports 240A-240D are shown in the example of FIGS. 2A and 2B, more or fewer loading ports may be provided in other examples of this technology.

The substrate handling chamber 210 is connected with multiple substrate processing chambers 280. Substrates are transferred into the substrate processing chambers 280 where one or more layers of material are deposited onto a surface of the substrate and/or other desired substrate processing takes place. FIGS. 2A and 2B show each substrate processing chamber 280 including four substrate supports 282 onto which substrates can be placed during processing. More or fewer substrate supports 282 may be provided in each substrate processing chamber 280 (e.g., the substrate processing chambers 280 may be dual chamber modules (DCM) or quad chamber modules (QCM)). Substrate processing chambers 280 in accordance with some examples of this technology may include another four substrate supports 282 located vertically beneath the four substrate supports 282 shown in the top views of FIGS. 2A and 2B. Each of the substrate processing chambers 280 may have the same structures or one or more of the substrate processing chambers 280 may have a different structure from other substrate processing chambers 280 present.

The substrate handling chamber 210 is connected with its respective substrate processing chambers 280 via one or more gate valves 250. While two gate valves 250 are shown connecting substrate handling chamber 210 with each of its respective substrate processing chambers 280, more or fewer gate valves 250 may be provided with each substrate processing chamber 280, in other examples of this technology. Substrate processing chambers 280 in accordance with some examples of this technology may be connected with substrate handling chamber 210 by another two gate valves 250, e.g., located vertically beneath the two gate valves 250 shown in the top views of FIGS. 2A and 2B. When closed, the gate valves 250 scalingly separate the substrate handling chamber 210 from its connected substrate processing chambers 280 (so that independent atmospheric conditions may be maintained in each chamber). When open, the gate valves 250 provide an opening (e.g., a substrate transfer slot) through which the end effector 212A of robotic arm 212 can extend to move substrates into and out of the substrate processing chamber 280. The openings through the gate valves 250 align with substrate transfer slots provided in the substrate processing chambers 280 and the substrate handling chamber 210 to enable substrates to be moved between the substrate processing chambers 280 and the substrate handling chamber 210 through the gate valves 250. Each of gate valves 250 may have the same structures or one or more of the gate valves 250 may have a different structure from other gate valves 250 present.

One side 224B of the load-lock module 220 connects with the equipment front end module 230 by one or more gate valves 260A, and the opposite side 224A of the load-lock module 220 connects with the substrate handling chamber 210 by one or more gate valves 260B. The load-lock module 220 further includes one or more substrate support setplates 222 (two setplates 222 shown in FIGS. 2A and 2B) for holding substrates while they wait to be moved into the equipment front end module 230 or the substrate handling chamber 210. When closed, the gate valves 260A, 260B sealingly separate the load-lock module 220 from the equipment front end module 230 and the substrate handling chamber 210 (so that independent atmospheric conditions may be maintained in each chamber). When open, the gate valves 260A provide an opening (e.g., a substrate transfer slot) through which the end effector 232A of robotic arm 232 can extend to move substrates into and out of the equipment front end module 230. The openings through the gate valves 260A align with substrate transfer slots provided in the equipment front end module 230 and substrate transfer slots 220S provided in the load-lock module 220 (see FIG. 2C) to enable substrates to be moved between the equipment front end module 230 and the load-lock module 220 through gate valves 260A. When open, the gate valves 260B provide an opening (e.g., a substrate transfer slot) through which the end effector 212A of robotic arm 212 can extend to move substrates into and out of the substrate handling chamber 210. The openings through the gate valves 260B align with substrate transfer slots provided in the substrate handling chamber 210 and the load-lock module 220 to enable substrates to be moved between the substrate handling chamber 210 and the load-lock module 220 through gate valves 260B. Each of gate valves 260A, 260B may have the same structure or one or more of the gate valves 260A, 260B may have a different structure from other gate valves 260A, 260B present.

As shown in FIG. 2C, the setplate(s) 222 may include a rack configured for holding a plurality of substrates 290, 292 in a spaced apart orientation (e.g., vertically spaced apart). The rack with setplates 222 may be movable in a vertical direction (see Arrows A) within the internal chamber 220A to allow a desired level of the setplate 222 to be oriented to align with the gate valve(s) 260A or 260B (to allow robotic arms 212, 232 to interact with a desired substrate and desired level on the setplate 222 rack).

Additional details of substrate cooling and/or heating systems and methods in accordance with some examples of this technology will be described in more detail. As mentioned above, substrates exiting the chambers in semiconductor deposition tools (such as substrate processing system 200) typically need to be cooled down before exposure to atmospheric conditions in order to maintain the performance integrity of the deposited films. In some examples, a substrate 290 may need to be cooled down several hundred degrees before exiting the substrate processing system 200 (e.g., to a temperature below 100° C.). In accordance with aspects of this technology, this cooling takes place in the load-lock module 220.

Thus, in accordance with aspects of this technology, substrate processing systems 200 (and methods) include two chambers in which gas is introduced into a first chamber (e.g., the load-lock module 220) from a second chamber (e.g., the equipment front end module 230). That gas is used to cool heated substrates 290 and/or to preheat substrates 292 to be processed while the substrates 290, 292 are located in the first chamber (e.g., the load-lock module 220). As shown in FIG. 2A, the load-lock module 220 of this example (also referred to as the “first chamber” herein) includes a first side 224A, a second side 224B opposite the first side 224A, and an internal chamber 220A defined between the first side 224A and the second side 224B. The first side 224A includes one or more openings (substrate transfer slots) that are configured to allow substrates to move to and from layer deposition equipment through gate valves 260B. The “layer deposition equipment” in this illustrated example comprises a “cluster type” substrate processing system 200 and includes the combination of the substrate handling chamber 210 and its connected substrate processing chambers 280 (although other types and/or arrangements of layer deposition equipment may be used). The second side 224B includes one or more openings (substrate transfer slots) that are configured to allow substrates to move to and from the equipment front end module 230 (also called the “second chamber” herein) through gate valves 260A.

The equipment front end module 230 in this illustrated example includes a first side 234A, a second side 234B opposite the first side 234A, and an internal chamber 230A defined between the first side 234A and the second side 234B. The first side 234A includes one or more openings (substrate transfer slots) that are configured to allow substrates to move to and from the load-lock module 220 through gate valves 260A. The second side 234B includes one or more openings that are configured to connect with the loading port(s) 240A-240D to allow substrates to move into and out of the equipment front end module 230 and into and out of the overall substrate processing system 200. At least one of gate valves 260A may be controlled by control system 320 to perform cooling and/or heating operations in accordance with aspects of this technology, as will be explained in more detail below.

In this illustrated example, the equipment front end module 230 also includes: (a) a gas inlet 230I (e.g., a gas port) for supplying gas to the internal chamber 230A of the equipment front end module 230, and (b) a gas exhaust outlet 230X (e.g., a gas port) for exhausting gas from the equipment front end module 230. In this illustrated example, the gas inlet 230I is connected to an inert gas source 300 (e.g., a nitrogen gas supply). Thus, the internal chamber 230A of the equipment front end module 230 may be maintained in an inert gas (e.g., a nitrogen gas) atmosphere under desired pressure conditions. The gas inlet 230I and gas exhaust outlet 230X may be equipped with valves to allow fluid flow into and out of the internal chamber 230A of the equipment front end module 230 to be selectively started, stopped, and controlled, e.g., to allow control of fluid flow rate and pressure within the internal chamber 230A.

FIG. 2A shows the substrate processing system 200 (and particularly the load-lock module 220 and equipment front end module 230) in a “normal” or “non-cooling” operational state. In this illustrated operational state, gate valves 260A are closed-including the at least one gate valve controlled by control system 320, as shown by the heavy black “X” at that gate valve 260A in FIG. 2A. Thus, in this operational state, the equipment front end module 230 is isolated from (scaled from) the load-lock module 220. In this operational state, different atmospheric conditions may be maintained in each of the equipment front end module 230 and the load-lock module 220. More specifically, the valves to gas inlet 230I and gas exhaust outlet 230X may be opened and inert gas (e.g., nitrogen) from inert gas source 300 can be contained within internal chamber 230A at any desired gas pressure (flowing from the gas inlet 230I to the gas exhaust outlet 230X, as shown by gas flow arrows 310 in FIG. 2A). Gas from inert gas source 300 and within the internal chamber 230A typically will be at a relatively low temperature (e.g., 100° C. or less). Load-lock module 220 may be maintained under vacuum conditions in this this operational state and/or may be opened at one or more of gate valves 260B to enable substrate exchange with substrate handling chamber 210.

FIGS. 2B and 2C show the substrate processing system 200 (and particularly the load-lock module 220 and equipment front end module 230) in a “cooling” and/or “heating” operational state. In this operational state, if necessary, the valve for the gas exhaust outlet 230X may be closed (or flow through gas exhaust outlet 230X may be slowed from the operational state shown in FIG. 2A). This is shown by the heavy, darkened “X” on gas exhaust outlet 230X in FIG. 2B. Additionally or alternatively, control system 320 may send signals to at least partially open gate valve 260A extending between the second side 224B of the load-lock module 220 and the first side 234A of the equipment front end module 230. Because the load-lock module 220 typically is under vacuum or low pressure conditions, the opening of gate valve 260A allows gas from the equipment front end module 230 to move through gate valve 260A and into the internal chamber 220A of the load-lock module 220 thereby providing a passageway (e.g., a gas passageway) between the equipment front end module 230 and the load-lock module 220. See gas flow arrows 312 in FIG. 2B. Gas exits the load-lock module 220 via gas exhaust outlet 220X. See gas flow arrow 314. In this manner, gas from the equipment front end module 230 enters and passes through the load-lock module 220.

As noted above, the gas from the equipment front end module 230 may be at a relatively low temperature (e.g., under 100° C.) as compared to the temperature of substrates 290 leaving the layer deposition equipment (e.g., substrate processing chambers 280 and/or substrate handling chamber 210). Thus, in accordance with aspects of this technology, the gas from the equipment front end module 230 (starting at less than 100° C.) may be used to cool substrates 290 (which may be several hundred degrees hotter) present in the load-lock module 220, e.g., on setplates 222. FIG. 2C shows a schematic view inside the internal chamber 220A of the load-lock module 220 during a cooling operational state (looking in a direction toward second side 224A). As described above, control system 320 at least partially opens one gate valve 260A (note opening 260O at the upper left gate valve 260A shown in FIG. 2C) which allows gas flow (arrow 312) from the equipment front end module 230 to pass through gate valve 260A and into the internal chamber 220A of the load-lock module 220. If necessary or desired, the gate valve 260A or a portion of the internal chamber 220A of the load-lock module 220 into which the gate valve 260A opens and located proximate to the gate valve 260A (e.g., the substrate transfer slot 220S) may be equipped with one or more baffles and/or deflectors 228 (or other gas flow direction control device(s)) to push the gas flow in a desired direction (pushing gas flow upward and toward the left in the example of FIG. 2C). In this manner, the incoming gas flow through the opening 260O in gate valve 260A will not directly contact the surface of a substrate 290 on the setplate 222 as it initially enters the internal chamber 220A (i.e., baffle(s) and/or deflector(s) 228 may initially deflect fluid flow away from the setplate 222 (or other substrate support member)).

Once inside the internal chamber 220A and directed to its initial desired location, the gas will flow toward the gas exhaust outlet 220X. In doing so, the gas will flow over (into contact with) and past substrates 290 on setplates 222. See gas flow arrows 314A. If the substrates 290 are heated as compared to the incident gas, this gas flow and contact with substrates 290 will result in heat transfer from the substrates 290 to the gas, thereby cooling the substrates 290 (and heating the gas). The location of the gas exhaust outlet 220X with respect to the gate valve 260A that is opened to allow gas flow to enter the internal chamber 220A also can be used to control the direction of gas flow within the internal chamber 220A.

As shown in FIG. 2C, in at least some examples of this technology, the gate valve(s) 260A controlled by control system 320 for the above cooling operational state need not be completely opened. Rather, the gate valve 260A may be partially opened, e.g., to control the rate of gas entry. Because the load-lock module 220 may be at vacuum or very low pressure conditions, abrupt opening of the gate valve 260A by control system 320 may result in very rapid gas transfer into the load-lock module 220, potentially causing substrates 290 to move on setplate(s) 222 and/or possibly damage them. Thus, in accordance with some examples of this technology, when opening gate valve 260A during a cooling operational state, the control system 320 may open the gate valve 260A slowly and/or a small initial amount, potentially followed by expanding the size of the opening 260O, as pressure within the load-lock module 220 increases. Control system 320 may control gate valve 260A to open in a stepwise or progressive manner (and/or in another suitable manner) to prevent disturbing the substrates 290 on the setplate(s) 222. As a more specific example, as noted above, the equipment front end module 230 includes robotic arm 232 used to transfer substrates between the equipment front end module 230 and the load-lock module 220 through gate valves 260A. During a substrate “cooling” operational state in accordance with some examples of this technology, the control system 320 initially will partially open gate valve 260A a sufficient amount (see opening 260O) to permit gas to pass from the internal chamber 230A of the equipment front end module 230 to the internal chamber 220A of the load-lock module 220 through the gate valve 260A but an insufficient amount to permit a substrate 290, 292 from being transferred through the gate valve 260A by the robotic arm 232. At later stages of this example substrate “cooling” operational state, the control system 320 may further open gate valve 260A, in some examples to a fully open configuration. At this time, in some examples, the gate valve 260A may be opened a sufficient extent to allow the robotic arm 232 to pass through the gate valve 260A and move the cooled substrates 290 into the equipment front end module 230 and/or move new substrates 292 for processing into the load-lock module 220.

As shown in FIG. 2C (along with FIG. 2B), in accordance with aspects of this technology, one or more substrate cooling zones (e.g., 226A) may be provided inside the internal chamber 220A of the load-lock module 220. The substrate cooling zone(s) 226A may include one or more setplates 222 or portions of setplates 222 located in regions of the internal chamber 220A of load-lock module 220 where heated substrates 290 can be placed when exiting the substrate handling chamber 210 through gate valves 260B. As the gas flows over these substrate cooling zone(s) 226A, heat is transferred from the heated substrates 290 to the cooling gas, as discussed above.

Further, in some examples of this technology, one or more substrate preheating zones 226B may be provided inside the internal chamber 220A of the load-lock module 220. The substrate preheating zone(s) 226B may include one or more setplates 222 or portions of setplates 222 located in regions of the internal chamber 220A of load-lock module 220 where new substrates 292 to be processed can be placed when entering the load-lock module 220 from the equipment front end module 230 through gate valves 260A. As evident from the gas flow arrows 314A and explanation above, the substrate preheating zone(s) 226B may be located in “downstream” regions of gas flow through the load-lock module 220 so that the cooler “entering” substrates 292 can be heated by the heated gas that already passed through the substrate cooling zone(s) 226A and picked up heat transferred from the heated substrates 290. This feature, when used, can reduce costs and processing time in heating up substrates 292 in the substrate handling chamber 210 before processing in substrate processing chamber(s) 280.

In the specific example of FIG. 2C, the left side setplate 222 rack is shown as a “cooling zone” 226A (boxed in by a broken line) and the right side setplate 222 is shown as a “preheating zone” 226B (boxed in by a dot-dash line). Thus, in some examples of this technology: (a) one setplate 222 rack may be designated as a cooling zone 226A and the rack on which heated substrates 290 leaving the layer deposition equipment are placed (for cooling) and (b) one setplate 222 rack may be designated as a preheating zone 226B and the rack on which new substrates 292 to be processed are placed (as they await entry into the layer deposition equipment). Such designated setplates 222 and/or designated setplate 222 racks, however, are not a requirement. In some examples of this technology: (a) a cooling zone 226A may exist at any location(s) where heated substrates 290 are placed (e.g., on one or more setplates 222) and/or at any location(s) where the gas moving through the load-lock module 220 is cooler than the substrates 290 at that location, and (b) a preheating zone 226B may exist at any location(s) where cool substrates 292 are placed (e.g., on one or more setplates 222) and/or at any location(s) where the gas moving through the load-lock module 220 is hotter than the substrates 292 at that location.

FIG. 2D illustrates an example substrate processing method in accordance with some examples of this technology, e.g., using the substrate processing system 200 described above in conjunction with FIGS. 2A-2C. In this method, first the gate valve(s) 260A between the equipment front end module 230 and the load-lock module 220 are closed (scaled) at Step S202. This isolates the load-lock module 220 from the equipment front end module 230 (each of which may have the structures described above). At Step S204, at least one processed substrate 290 is moved from the layer deposition equipment (e.g., from one of the substrate processing chambers 280 via substrate handling chamber 210) into the load-lock module 220 via one of gate valves 260B using robotic arm 212. The processed substrate 290 typically will be at an elevated temperature from the layer deposition equipment and will be placed on one of the setplates 222. Then the gate valve(s) 260B are sealed at Step S206 to isolate the load-lock module 220 from the substrate handling chamber 210.

To cool the substrate(s) 290 in accordance with some examples of this technology, at least one gate valve 260A between the load-lock module 220 and the equipment front end module 230 will be (at least) partially opened at Step S208 (e.g., as described above with respect to opening 260O). This action allows gas from the equipment front end module 230 (e.g., inert nitrogen gas from the atmosphere maintained in the equipment front end module 230) to move into the load-lock module 220 through the partially open gate valve 260A at Step S210 and flow over the heated substrate(s) 290, e.g., in the manners described above in conjunction with FIGS. 2B and 2C. The inert gas transferred into the load-lock module 220 from the equipment front end module 230 via gate valve 260A may be exhausted from the load-lock module 220 via gas exhaust outlet 220X. Control system 320 may control (and adjust) the degree of opening of gate valve 260A to control fluid flow rate into the load-lock module 220 via opening 260O.

One or more temperature sensors may be provided (e.g., in or associated with the load-lock module 230) to measure temperature of the substrate 290 (e.g., thermocouple type sensors with setplates 222, contactless pyrometer type sensors, etc.), and the system/method may determine if the substrate 290 is adequately cooled at Step S212. If not (answer “NO” at Step S212), the method can continue with Step S210 until adequate cooling is achieved (answer “YES” at Step S212). Once adequate cooling has been accomplished, the partially open gate valve 260A can be further opened (Step S214) or another gate valve 230A can be opened, and the cooled substrate 290 can be moved from the load-lock module 220 into the equipment front end module 230 at Step S216 using robotic arm 232. From there, the substrate 290 can be moved into a loading port 240A-240D and transferred out of the substrate processing system 200.

Methods of the types described above in conjunction with FIG. 2D also may include preheating incoming substrates 292 in the load-lock module 230 (substrates 292 that are moving toward the layer deposition equipment for processing) using gas that has picked up heat from the heated substrates 290 before the gas passes through gas exhaust outlet 220X.

FIGS. 2A-2D show an example of this technology where one of the gate valves 260A through which substrates 290, 292 are transferred between the equipment front end module 230 and the load-lock module 220 provides a passageway through which gas moves for a substrate cooling operation. This is not a requirement. For example, if desired, two or more of the gate valves 260A could be controlled by control system 320 and selectively opened to permit gas to flow from the equipment front end module 230 to the load-lock module 220 for a cooling and/or heating operational state. When multiple gate valves 260A are controllable in this manner, they may operate together (e.g., in tandem), or they may be separately controllable.

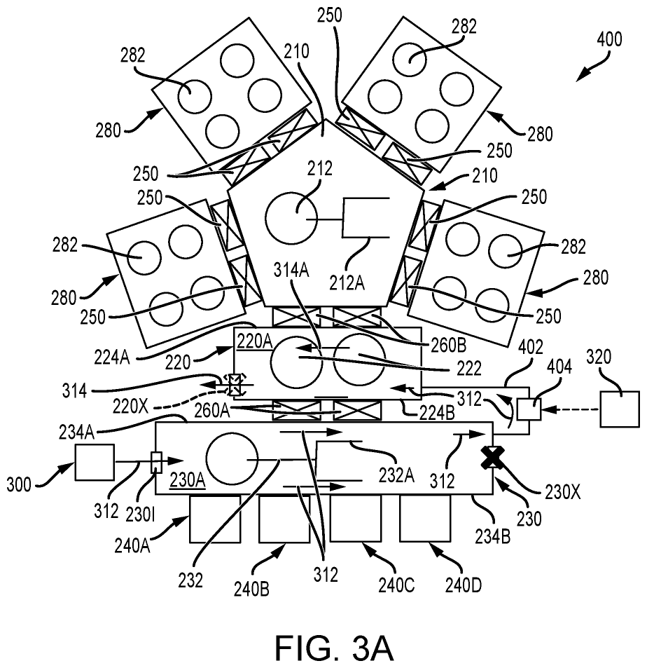

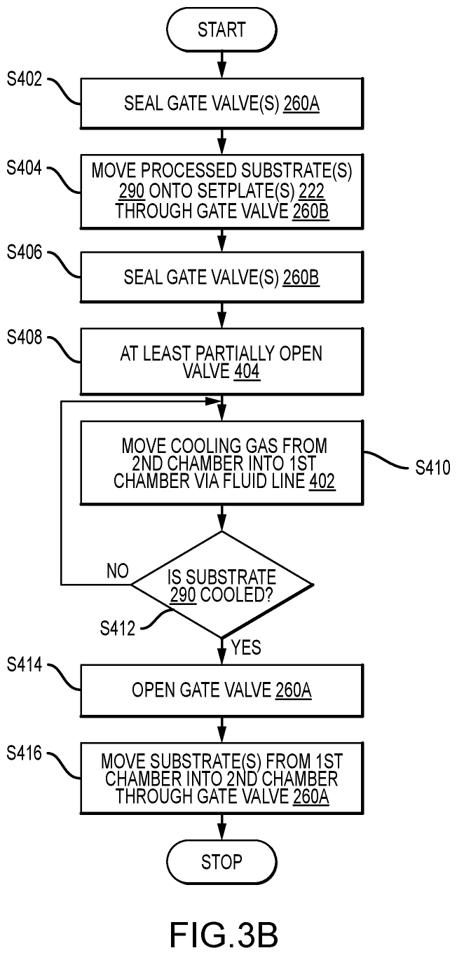

FIG. 3A illustrates another alternative example substrate processing system 400 in accordance with some examples of this technology. Where the same reference number is used in FIG. 3A as used in FIGS. 2A-2C, the same or similar parts are being referenced, and much of the repetitive description may be omitted. The description of FIG. 3A below will focus primarily on the manner in which substrate processing system 400 differs from substrate processing system 200 of FIGS. 2A-2C.

As shown in FIG. 3A, a fluid line 402 including an electronically controllable valve 404 is provided as a passageway to selectively place the internal chamber 230A of the equipment front end module 230 in fluid communication with the internal chamber 220A of the load-lock module 220. Electronically controllable valve 404 may be controlled by control system 320 in a manner similar to the manner in which control system 320 controls gate valve 260A to place the substrate processing system 400 in a “normal” or “non-cooling” operational state and a substrate “cooling” and/or “heating” operational state. More specifically, in the “normal” or “non-cooling” operational state, electronically controllable valve 404 will be closed, and any desired operations may take place. In that operational state, gas exhaust outlet 230X may be opened and an inert gas (e.g., nitrogen) atmosphere may be maintained in the internal chamber 230A of the equipment front end module 230, e.g., in the same general manner shown in FIG. 2A. Thus, in this operational state, the equipment front end module 230 may be isolated from (scaled from) the load-lock module 220, and different atmospheric conditions may be maintained in each of the equipment front end module 230 and the load-lock module 220. More specifically, the valves to gas inlet 230I and gas exhaust outlet 230X may be opened and inert gas (e.g., nitrogen) from inert gas source 300 can be contained within internal chamber 230A at any desired gas pressure (flowing from the gas inlet 230I to the gas exhaust outlet 230X). Gas from inert gas source 300 and within the internal chamber 230A typically will be at a relatively low temperature (e.g., 100° C. or less). Load-lock module 220 may be maintained under vacuum conditions in this this operational state (and/or may be opened at one or more gate valve(s) 260B to enable substrate exchange with substrate handling chamber 210).

FIG. 3A shows the substrate processing system 400 of this example in a “cooling” and/or “heating” operational state. In this operational state, if necessary, the valve for the gas exhaust outlet 230X may be closed (or flow through gas exhaust outlet 230X may be slowed from the “non-cooling” operational state described above). This is shown by the heavy, darkened “X” on gas exhaust outlet 230X in FIG. 3A. Additionally or alternatively, control system 320 may send signals to at least partially open electronically controllable valve 404 in fluid line 402 (or other gas passageway) extending between the load-lock module 220 and the equipment front end module 230. Because the load-lock module 220 typically is under vacuum or low pressure conditions, the opening of electronically controllable valve 404 allows gas from the equipment front end module 230 to move through electronically controllable valve 404 and into the internal chamber 220A of the load-lock module 220 (thereby providing a gas passageway between the equipment front end module 230 and the load-lock module 220). See gas flow arrows 312 in FIG. 3A. Gas exits the load-lock module 220 via gas exhaust outlet 220X. See gas flow arrows 314A and 314. In this manner, gas from the equipment front end module 230 enters and passes through the load-lock module 220.

As noted above, the gas from the equipment front end module 230 may be at a relatively low temperature (e.g., under 100° C.) as compared to the temperature of substrates 290 leaving the layer deposition equipment (e.g., substrate processing chambers 280 and/or substrate handling chamber 210). Thus, in accordance with aspects of this technology, the gas from the equipment front end module 230 (starting at less than 100° C.) may be used to cool substrates 290 (which may be several hundred degrees hotter) present in the load-lock module 220, e.g., on setplates 222. This cooling operation may proceed in the same manner generally described above in conjunction with FIGS. 2B and 2C. As described above, control system 320 at least partially opens electronically controllable valve 404 which allows gas flow (arrow 312) from the equipment front end module 230 to pass through electronically controllable valve 404 and into the internal chamber 220A of the load-lock module 220. If necessary or desired, the area around the location where gas enters the internal chamber 220A of the load-lock module 220 via fluid line 402 may be equipped with one or more baffles and/or deflectors (or other gas flow direction control devices) to push the gas flow in a desired direction. In this manner, the incoming gas flow through the electronically controllable valve 404 will not directly contact the surface of a substrate 290 on the setplate 222 as it enters the internal chamber 220A (e.g., baffle(s) and/or deflector(s) may initially deflect fluid flow away from the setplate 222 (or other substrate support member)).

Once inside the internal chamber 220A and directed to its initial desired location, the gas will flow toward the gas exhaust outlet 220X. In doing so, the gas will flow over (into contact with) and past substrates 290 on setplates 222, e.g., in the general manner described above in conjunction with FIG. 2C. See gas flow arrow 314A in FIG. 3A. If the substrates 290 are heated as compared to the incident gas, this gas flow and contact with substrates 290 will result in heat transfer from the substrates 290 to the gas, thereby cooling the substrates 290 (and heating the gas). The location of the gas exhaust outlet 220X with respect to the inlet for fluid line 402 in internal chamber 220A also can be used to control the direction of gas flow within the internal chamber 220A.

In at least some examples of this technology, the electronically controllable valve 404 controlled by control system 320 for the above cooling operational state need not be completely opened. Rather, the electronically controllable valve 404 may be partially opened, e.g., to control the rate of gas entry. Because the load-lock module 220 may be at vacuum or very low pressure conditions, abrupt opening of the electronically controllable valve 404 by control system 320 may result in very rapid gas transfer into the load-lock module 220, potentially causing substrates 290 to move on setplate(s) 222 and/or possibly damage them. Thus, in accordance with some examples of this technology, when opening electronically controllable valve 404 during a cooling operational state, the control system 320 may open the electronically controllable valve 404 slowly and/or a small initial amount, potentially followed by an increased amount, as pressure within the load-lock module 220 increases. Control system 320 may control electronically controllable valve 404 to open in a stepwise or progressive manner (and/or in other suitable manner) to prevent disturbing the substrates 290 on the setplate(s) 222.

Further, the substrate processing system 400 of FIG. 3A further may be arranged to provide one or more substrate cooling zones and/or one or more substrate “preheating” zones, e.g., substrate cooling zones 226A and/or substrate preheating zones 226B as described above in conjunction with FIG. 2C. In the same manner described above in conjunction with FIG. 2C, in the substrate processing system 400 of FIG. 3A, the substrate preheating zone(s) 226B may be located in “downstream” regions with respect to gas flow through the load-lock module 220 so that the cooler “entering” substrates 292 can be heated by the heated gas that already passed through the “upstream” substrate cooling zone(s) 226A and/or picked up heat transferred from the heated substrates 290.

FIG. 3B illustrates an example substrate processing method in accordance with some examples of this technology, e.g., using the substrate processing system 400 described above in conjunction with FIG. 3A. In this method, first the gate valve(s) 260A between the equipment front end module 230 and the load-lock module 220 are closed (scaled) at Step S402. This isolates the load-lock module 220 from the equipment front end module 230 (each of which may have the structures described above). At Step S404, at least one processed substrate 290 is moved from the layer deposition equipment (e.g., from one of the substrate processing chambers 280 via substrate handling chamber 210) into the load-lock module 220 via one of gate valves 260B using robotic arm 212. The processed substrate 290 typically will be at an elevated temperature from the layer deposition equipment and will be placed on one of the setplates 222. Then the gate valve(s) 260B are sealed at Step S406 to isolate the load-lock module 220 from the substrate handling chamber 210.

To cool the substrate(s) 290 in accordance with some examples of this technology, electronically controllable valve 404 in fluid line 402 (extending between the load-lock module 220 and the equipment front end module 230) will be at least partially opened at Step S408 by control system 320. This action allows gas from the equipment front end module 230 (e.g., inert nitrogen gas from the atmosphere maintained in the equipment front end module 230) to move into the load-lock module 220 at Step S410 and flow over the heated substrate(s) 290, e.g., in the manners described above in conjunction with FIGS. 2C and 3A. The inert gas transferred into the load-lock module 220 from the equipment front end module 230 via electronically controllable valve 404 and fluid line 402 may be exhausted from the load-lock module 220 via gas exhaust outlet 220X. Control system 320 may control (and adjust) the degree of opening of electronically controllable valve 404 to control fluid flow rate into the load-lock module 220 via fluid line 402.

As noted above, one or more temperature sensors may be provided (e.g., in or associated with the load-lock module 230) to measure temperature of the substrate 290 (e.g., thermocouple type sensors with setplates 222, contactless pyrometer type sensors, etc.), and the system/method may determine if the substrate 290 is adequately cooled at Step S412. If not (answer “NO” at Step S412), the method can continue with Step S410 until adequate cooling is achieved (answer “YES” at Step S412). Once adequate cooling has been accomplished, a gate valve 260A can be opened (Step S414), and the cooled substrate 290 can be moved from the load-lock module 220 into the equipment front end module 230 through gate valve 260A at Step S416 using robotic arm 232. From there, the substrate 290 can be moved into a loading port 240A-240D and transferred out of the substrate processing system 400.

Methods of the types described above in conjunction with FIG. 3B also may include preheating incoming substrates 292 in the load-lock module 230 (substrates 292 that are moving toward the layer deposition equipment for processing) using gas that has picked up heat from the heated substrates 290 before the gas passes through gas exhaust outlet 220X.

While the noted specific examples of this technology discussed above in conjunction with FIGS. 2A-3B described cooling substrates in a first chamber (e.g., a load-lock module) using gas moved into the first chamber from a second chamber (e.g., an equipment front end module), similar systems and methods could be provided to heat substrates in a first chamber using gas moved into the first chamber from a second chamber, e.g., if the incoming gas from the second chamber is at a higher temperature than the substrates in the first chamber. In such heating systems, when heating substrates in this manner, a downstream “cooling” region could be provided where heated substrates are cooled by the gas that has already passed over (and heated) upstream substrates. Additionally, aspects of this technology may be applied to chambers used in environments other than “cluster type” substrate processing systems.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system, comprising:
a first chamber including:
a first side,
a second side opposite the first side,
a first internal chamber defined between the first side and the second side, and
an exhaust outlet that exhausts gas from the first internal chamber,
wherein the first side includes one or more openings that are configured to allow substrates to move to and from layer deposition equipment;
a second chamber including:
a third side,
a fourth side opposite the third side,
a second internal chamber defined between the third side and the fourth side, and
a gas inlet supplying gas to the second internal chamber,
wherein the fourth side includes one or more openings that are configured to allow substrates to enter and exit the substrate processing system;
a first passageway connecting the first chamber with the second chamber;
a first valve configured to control fluid flow through the first passageway; and
a control system configured to at least partially open the first valve during a substrate cooling operation to allow gas from the second internal chamber to enter the first internal chamber through the first passageway, flow through the first internal chamber, and out of the first internal chamber via the exhaust outlet.

2. The substrate processing system according to claim 1, wherein the first chamber further includes: (i) a substrate support member, and (ii) a gas flow direction control device located proximate to an opening in communication with the first valve to direct at least some gas flow entering through the opening via the first passageway away from the substrate support member.

3. The substrate processing system according to claim 1, wherein the first valve is a first gate valve connecting the second side of the first chamber with the third side of the second chamber and defining at least a portion of the first passageway, wherein at least one of the first chamber or the second chamber includes a substrate transfer arm for moving substrates between the first chamber and the second chamber through the first gate valve, wherein during the substrate cooling operation, the control system partially opens the first gate valve a sufficient amount to permit gas to pass from the second internal chamber to the first internal chamber through the first gate valve but an insufficient amount to permit a substrate from being transferred through the first gate valve by the substrate transfer arm.

4. The substrate processing system according to claim 1, further comprising a gas source connected to the gas inlet and supplying gas to the second internal chamber.

5. The substrate processing system according to claim 4, wherein the gas source is a nitrogen gas source.

6. The substrate processing system according to claim 1, wherein the first valve is a first gate valve connecting the second side of the first chamber with the third side of the second chamber and defining at least a portion of the first passageway, wherein the control system is configured to partially open the first gate valve during the substrate cooling operation, and wherein the control system further is configured to more fully open the first gate valve to permit substrate transfer from the first chamber to the second chamber through the first gate valve when the substrate cooling operation is complete.

7. The substrate processing system according to claim 1, wherein the first valve is a first gate valve connecting the second side of the first chamber with the third side of the second chamber and defining at least a portion of the first passageway, the first gate valve including an opening configured to transfer substrates between the first chamber and the second chamber.

8. The substrate processing system according to claim 7, wherein the first chamber includes: (i) a substrate support member located proximate to the first gate valve, and (ii) a gas flow direction control device positioned to direct at least some gas flow entering the first internal chamber via the first gate valve away from the substrate support member.

9. The substrate processing system according to claim 8, wherein the substrate support member includes a rack configured for holding a plurality of substrates in a spaced apart orientation.

10. The substrate processing system according to claim 7, wherein the first chamber defines: (i) a substrate cooling zone to support substrates moved from the layer deposition equipment into the first chamber, and (ii) a substrate preheat zone to support substrates moved from the second chamber to the first chamber via the first gate valve, wherein the substrate preheat zone is located downstream from the substrate cooling zone in a gas direction through the first internal chamber.

11. The substrate processing system according to claim 7, further comprising a second gate valve connecting the second side of the first chamber with the third side of the second chamber, wherein the second gate valve includes an opening configured to transfer substrates between the first chamber and the second chamber.

12. The substrate processing system according to claim 1, further comprising a second valve connecting the second side of the first chamber with the third side of the second chamber, wherein the second valve includes an opening configured to transfer substrates between the first chamber and the second chamber.

13. A substrate processing method, comprising:
sealing a first gate valve connecting a first chamber and a second chamber, wherein a first side of the first chamber is connected to layer deposition equipment and a second side of the first chamber is connected to the second chamber via the first gate valve, wherein the second chamber is configured to receive (i) incoming substrates to be supplied to the first chamber through the first gate valve and (ii) outgoing substrates to be removed from the first chamber through the first gate valve;
moving a first processed substrate from the layer deposition equipment to the first chamber;
supplying an inert gas atmosphere to the second chamber;
cooling the first processed substrate by transferring inert gas from the second chamber into the first chamber such that the inert gas flows into contact with the first processed substrate; and
exhausting the inert gas from the first chamber.

14. The substrate processing method according to claim 13, wherein the transferring the inert gas includes partially opening the first gate valve a first amount, wherein the first amount is sufficient to transfer the inert gas but not sufficient to allow a substrate to be transferred through the first gate valve.

15. The substrate processing method according to claim 14, wherein after the first processed substrate is cooled, further opening the first gate valve to a second amount and moving the first processed substrate from the first chamber to the second chamber through the first gate valve.

16. The substrate processing method according to claim 13, further comprising:
moving a first unprocessed substrate to a substrate support member located in the first chamber; and
preheating the first unprocessed substrate by moving the inert gas in a direction from the first processed substrate to the first unprocessed substrate.

17. The substrate processing method according to claim 16, further comprising after preheating, moving the first unprocessed substrate through an opening defined through the first side of the first chamber to the layer deposition equipment.

18. The substrate processing method according to claim 13, wherein the inert gas is nitrogen gas.

19. The substrate processing method according to claim 13, wherein during the cooling, the inert gas is transferred through the first gate valve.

20. The substrate processing method according to claim 13, wherein the transferring the inert gas from the second chamber into the first chamber takes place through a valve other than the first gate valve.
